(19) United States
(12) Patent Application Publication
(10) Pub. No.: US 2005/0063439 A1
(43) Pub. Date: Mar. 24, 2005

(54) Laser source in guided optics

(76) Inventors: Olivier Dellea, Meylan (FR); Engin Molva, Grenoble (FR)

Correspondence Address: PILLSBURY WINTHROP, LLP, P.O. BOX 10500, MCLEAN, VA, 22102, US

(21) Appl. No.: 10/487,249

(22) PCT Filed: Aug. 21, 2002
(86) PCT No.: PCT/FR02/02915

(30) Foreign Application Priority Data
Aug. 23, 2001 (FR) 01/11043

(51) Int. Cl. H01S 5/00

(52) U.S. Cl. 372/50; 372/108

(57) ABSTRACT

A laser source includes a first optical element and a second optical element spaced apart from each other and defining a laser cavity therebetween. The laser cavity with a lasing material therein are capable of emitting an optical beam. The laser source also includes a guided optical element formed on a substrate. The guided optical element includes a mirror which is concave in at least one guide plane of an input guide area of the guided optical element. The mirror forms an extended laser cavity with the laser cavity. The guided optical element also includes a microguide associated with an optical output of the laser source. The microguide defines an output area of the guided optical element. The input guide area is capable of receiving the optical beam emitted by the laser cavity and capable of transmitting the optical beam to an adaptor guide area located between the input guide area and the microguide. The adaptor guide area is capable of guiding the optical beam to the microguide.

### CROSS-REFERENCE TO RELATED APPLICATIONS

This application is based on and claims priority to application No. 01/11043 filed in France on Aug. 23, 2001 and to international application No. PCT/FR02/002915 filed on Aug. 21, 2002, the entire contents of each of which are hereby incorporated by reference.

### BACKGROUND OF THE INVENTION

1. Field of the Invention

This invention relates to a guided optical laser source. More particularly, it relates to a laser source capable of emitting a high power light wave with one or several modes.

2. Description of Related Art

Presently, systems developed for optical telecommunications for regenerating a beam propagating in an optical fibre use optical amplifiers. Currently, optical wave guides used in optical amplifiers are generally single mode or multi-mode with few modes. Consequently, optical amplifiers are usually pumped by pump laser diodes that are single mode or multi-mode with few modes, in order to be compatible for coupling with the optical guides.

In the present state of the art, laser diodes with one or few modes have a low power and have a high cost, while high power laser diodes (particularly pump laser diodes with a wide ribbon) are multi-mode and therefore incompatible with coupling with optical guides.

More generally, known high power laser sources are usually multi-mode. This creates mode matching problems and thus coupling problems with optical guides designed for propagation and/or transformation of the light wave output from the high power laser sources. On the other hand, laser sources that have one or a few modes are low power.

An optical guide can be a planar guide, a microguide or an optical fibre.

A microguide can be a guide with lateral confinement, unlike a planar guide in which light may propagate in a plane, i.e., the guide plane.

### BRIEF SUMMARY OF THE INVENTION

An aspect of an embodiment of this invention is to propose a guided optical laser source without the limitations and difficulties of the laser sources mentioned above.

In particular, one aspect of an embodiment of the invention is to propose a laser source with a very good optical beam quality. A good optical beam quality is a beam with one or few modes, in other words a beam close to the diffraction limit.

Another aspect of an embodiment of the invention is to propose a laser source that can have a high power.

Another aspect of an embodiment of the invention is to propose a low cost and easy-to-build laser source.

The guided optical laser source can be used in applications in all fields requiring a laser source with few modes, and in particular for optical telecommunications, for example as a pump source for optical amplifiers or in domains such as medicine, spectroscopy or metrology using single mode laser sources or slightly multi-mode laser sources.

One embodiment of the guided optic laser source includes a laser cavity capable of emitting an optical beam, a guided optical element having: an input guide area comprising a mirror that is concave in at least one guide plane of the input area, so as to form an extended laser cavity with the laser cavity, an output area comprising at least one microguide and, a planar adaptor guide area between the input area and the microguide, the input guide area being capable of receiving an optical beam emitted by the laser cavity and transmitting the optical beam to the adaptor guide area. The adaptor guide area being capable of guiding the optical beam to the microguide that is associated with at least one optical output from the source.

The laser source according to one embodiment of the invention can produce an output beam from the microguide that has only one to a few modes, even if the laser cavity emits a multi-mode beam. Moreover, power losses of the output beam in the guided optical element are low, which allows to obtain a high power laser source if the laser cavity emits a high power optical beam.

Thus, the guided optical element of the laser source according to one embodiment of the present invention is capable of reducing the number of modes in a light wave so that the laser source is compatible with single mode guided optical components or compatible with slightly multi-mode optical components. Consequently, the laser cavity according to an embodiment of the present invention can be chosen for its power characteristics without any constraints on the number of modes in the emitted wave.

According to one embodiment of the invention, a planar guide is an optical guide along a guide plane. The orientations of the guide plane may be different depending on the position of the guide in the guided optical element and the type of guide. In particular, the planar guide may be at variable depths in the guided optical element. The same is true for microguides that may be more or less buried.

According to one embodiment of the invention, the laser cavity is a laser diode comprising at least one plane mirror.

All types of laser diodes may be used, and for example laser diodes with wide ribbon, multi-ribbon laser diodes, laser diodes with Bragg grating, Vertical Cavity Surface Emitting Laser (VCSEL) diodes, etc.

The laser cavity may be arranged directly on the guided optical element, at the input guide area to the guided optical element, using any conventional assembly techniques, and for example by using a support capable of maintaining the cavity and the optical element.

The laser cavity may also be arranged facing the input guide area such that there is a free space area between the cavity and the input guide area.

The guided optical element can be made in integrated optics starting from a single layer or multi-layer substrate in which the input area, an adaptor area and the output area are formed. According to one preferred embodiment, the substrate is made of glass and the guides and microguides of this optical element are made using ion exchange techniques in glass or by deposition of layers.

The input guide area comprises a planar guide connected to the adaptor guide area through the concave mirror that can be made by introducing a local variation of the effective index of the planar guide. The length L₁ of this area along the propagation direction of the beam depends on the optical length L of the source. This optical length depends on the medium through which the optical beam passes as it travels towards the mirror. The medium is composed of the cavity medium that essentially corresponds to the medium of the laser material, possibly a medium in free space and the medium formed by the input area guide. Thus, in some cases, the concave mirror may be arranged directly at the input to the optical element, which reduces the length of the input area to the bow h of the concave mirror.

The mirror in the optical element is concave in at least one guide plane. It can be made by a local variation of the effective index of the guide at the input area. This index variation may be obtained particularly by a cavity located in the substrate above the planar guide, by local deposition of at least one layer on the substrate above the plane guide, by local burying of the planar guide by an ion exchange located in the substrate above the planar guide or by a Bragg grating in the substrate above the planar guide. This list is not exhaustive and other embodiments of the concave mirror can be used to make the optical element according to the invention.

According to one embodiment of the invention, the concave mirror is also capable of filtering one or several wavelengths of the beam emitted by the laser cavity, by selectively reflecting the wavelengths. In this case, the laser cavity can be made using a mirror formed by a Bragg grating.

In order for the laser source according to one embodiment of the invention to be optically stable, in other words in order to set up at least one stable optical mode, the radius of curvature R of the concave mirror must be greater than or equal to the optical length L of the source defined by the relation L=n_{c}.L_{c}+nₑ.D+n₁.L₁ where n₁ is the effective index of the input guide area and n_{c}, nₑ are the refraction indexes of the material in the laser cavity and the medium in the free area between the cavity and the guided optical element, respectively. L_{c}, D, L₁ are the cavity lengths, the free space area between the cavity and the guided optical element, and the input area, respectively.

When the cavity is arranged directly on the guided optical element, then D=0 and L=n_{c}.L_{c}+n₁.L₁.

Thus, as mentioned above, the concave mirror has a radius of curvature R and is located at a distance from the laser cavity such that it forms an extended laser cavity with the input area, the medium inserted between the cavity and the guided optical element and the laser cavity. The concave mirror is capable of transmitting part of the laser beam set up in the extended cavity. The reflectivity of the concave mirror is partial (a few % to a few tens of %).

The geometrical characteristics of the concave mirror obey the following equalities and inequalities:

$${W}_{0}^{2} = {\frac{λ}{π} [ L . ( R - L ) ]}^{1 / 2} and 2 {w}_{0} > {1}_{r}$$

$${w}^{2} = {\frac{λ R}{π} [ L / ( R - L ) ]}^{1 / 2}$$

$$R > L$$

$$L = {n}_{c} . {L}_{c} + ne . D + {n}_{1} . {L}_{1}$$

$$H / R = 1 - {( 1 - {d}^{2 /} 4 {R}^{2} )}^{1 / 2}$$

$$d > 2 W$$

where λ is the wavelength considered of the light beam, w₀ is the radius of the beam on the plane mirror of the cavity, lᵣ is the width of the ribbon of the laser cavity, R is the radius of curvature of the concave mirror, L is the optical length of the source, w is the radius of the light beam on the concave mirror, h is the bow of the concave mirror in the guide plane and d is the diameter of the concave mirror.

According to one embodiment, focusing components, for example collimators, are inserted between the laser cavity and the guided optical element to optimize coupling between the laser cavity and the input of the guided optical element in at least a plane perpendicular to the input area guide plane and perpendicular to the direction of propagation of the light beam.

In one embodiment, the adaptor guide area comprises a planar guide in the form of a taper, at least in the guide plane of the guide. The adaptor area concentrates the light power of the optical beam in the microguide of the output area.

The adaptor guide area is adiabatic to enable a slow transition between the planar guide and the microguide and thus to minimize losses of the light power.

According to one embodiment, the laser source according to an embodiment of the invention also comprises at least one divider with one input and n outputs. In the output area from the guided optical element, the input of the divider is connected to the microguide such that the n divider outputs act as n outputs from the source.

According to one variant embodiment of the invention, the laser source also comprises x couplers (where x is an integer greater than or equal to 1) in the output area from the guided optical element. Each coupler is associated with the microguide, such that the microguide and each of the couplers form an output from the source, respectively.

One aspect of the present invention is thus the capability of making a laser source with several emission outputs. The light beam emitted at each of these outputs is single mode or slightly multi-mode.

Other aspects of the invention will become clear after reading the following description with reference to the figures in the attached drawings.

### BRIEF DESCRIPTION OF THE DRAWINGS

FIG. 1 diagrammatically shows a cross-section through the source according to a first embodiment of the invention;

FIG. 2 is a cross-section through a variant of the first embodiment showing the focusing components;

FIG. 3 diagrammatically shows a cross-section through the source according to a second embodiment of the invention;

FIG. 4 diagrammatically shows a cross-section through a laser source with several optical outputs according to an embodiment of the invention;

FIG. 5 diagrammatically shows a cross-section through another laser source with several optical outputs according to an embodiment of the invention; and

FIGS. 6a to 6e illustrate a cross-section showing examples of concave mirrors that can be used in various embodiments of the invention.

### DETAILED DESCRIPTION OF THE INVENTION

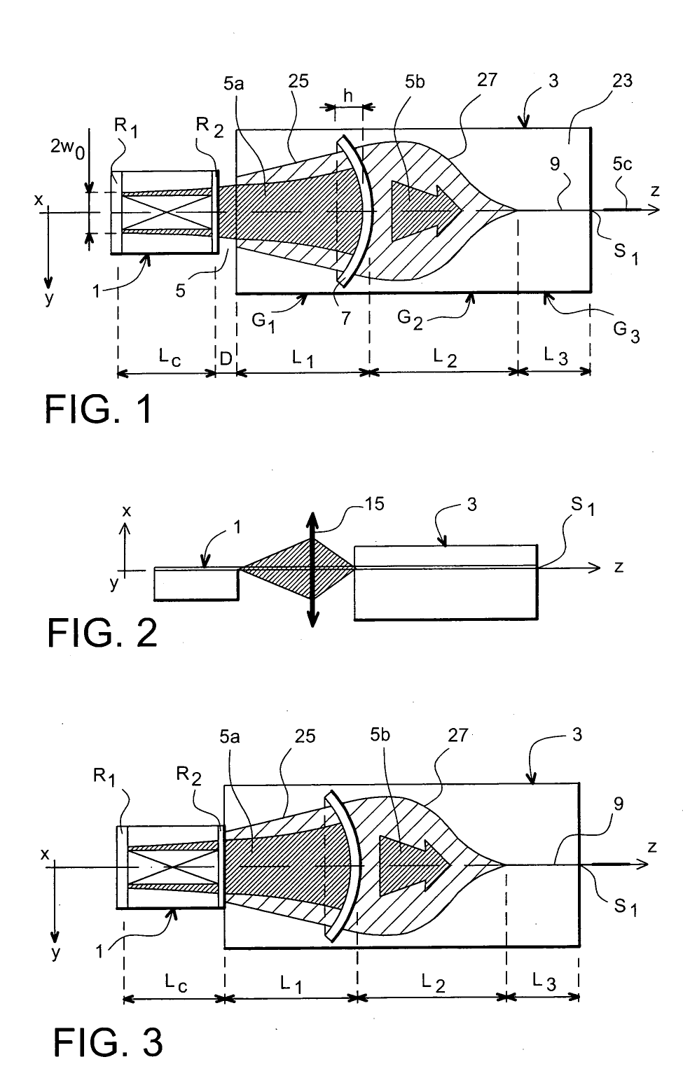

FIG. 1 illustrates a sectional view of the source according to a first embodiment of the invention. The cross-section is made according to guide plane yz.

This source essentially comprises a laser cavity 1 capable of emitting an optical beam 5 and a guided optical element 3.

For example, the laser cavity is a single ribbon laser diode, for example, capable of having a high power optical beam 5. For example, we can take a transverse multi-mode laser diode with a 100 μm wide ribbon emitting an optical power of 1 to 2 W. This laser cavity includes two optical elements, e.g. mirrors R₁ and R₂. The mirror R₁ is highly reflecting, for example of the order of 80% and the mirror R₂ is non-reflecting or is only slightly reflecting, for example of the order of a few % or even less.

The guided optical element 3 is essentially composed of three parts:
an input guide area G₁ comprising a concave mirror 7, the curvature of the mirror being defined at least in the guide plane yz of the input area;
an output area G₃ comprising at least one microguide 9; and
a planar adaptor guide area G₂ between the input area G₁ and the microguide 9. The input guide area is capable of receiving the optical beam 5 emitted by the cavity 1 and transmitting it through the concave mirror 7 to the adaptor guide area G₂, which is capable of guiding the optical beam towards the microguide 9 associated with at least one optical output S₁ from the source.

The guided optical element 3 is advantageously made of integrated optics starting from a single layer or multi-layer substrate 23 in which the input area, the adaptor area and the output area are formed. For example, the substrate is a glass substrate and the guides and microguides of this element 3 are made using ion exchange techniques in glass.

The guide plane is the same in this figure and in the other figures for the different parts of the source, but when the guides are more or less buried, the guide plane of the different parts, or even the guide plane in each part, may be in different planes.

Only the core of the guides is shown in these figures, for simplification reasons.

In this embodiment, the input area G₁ comprises a planar guide referenced 25. This guide 25 extends over the entire length L₁ of the area G₁ and gets wider along the y axis from the guide input to its end at the concave mirror 7.

The divergent shape of the planar guide enables the light beam 5a output from the laser cavity to propagate freely in the area G₁ and obtain a stable extended laser cavity.

The planar guide can be any other shape provided that its dimensions along the y axis are greater than the dimensions along the same axis of the guided optical beam 5a, in G₁.

In area G₁, the optical beam has one or several widened modes in the yz plane.

The curvature of the mirror is defined in the yz plane. The axis of symmetry of the mirror in this plane corresponds to the z axis which is the direction of propagation of the light beam.

This concave mirror can be used to make an extended laser cavity. It transmits the light beam 5a output from the laser cavity 1 guided by the planar guide 25 of the input area. This mirror is partially reflecting. Its reflectivity may be, for example, a few % to a few tens of

The mirror can also be used as a filter, for example a wavelength filter, such that the mirror 7 only transmits a light beam 5b with one or several selected wavelengths to the area G₂.

This mirror is advantageously made by making a local variation of the effective index of the planar guide 25.

The adaptor guide area G₂, that is optically connected to the plane guide 25 through the concave mirror, is designed to focus the optical beam broadened in space in the microguide 9.

This adaptor area G₂ is made using a planar guide 27 in which the width along the y axis decreases from area G₁ to area G₃, until the width is equal to the width of the microguide 9 to which it is optically connected.

Preferably, the planar guide 27 is made to converge adiabatically from G₁ to the microguide 9 to minimise optical losses in the guide.

This taper shaped convergence of the planar guide 27 is at least in the yz guide plane of the guide. The length of this area G₂ is L₂. It is determined so as to concentrate the light power from the light beam transmitted by the mirror, in the microguide 9.

Finally, the length of the last area G₃ is L₃ and it has at least one microguide 9 that brings the light beam output from the adaptor area to an output S₁ of the guided optical element.

The output S₁ could be on one face of the substrate 23 perpendicular to the z axis, as shown in this figure. However, it could also be on another face of this substrate 23.

In the example in FIG. 1, the light beam 5 propagates between the cavity 1 and the element 3 over a distance D within a free space area. Therefore, the medium through which the optical beam passes is composed of the medium of the cavity 1 corresponding essentially to the medium of the laser material, the medium in the area in free space (usually air) and the medium formed by the planar guide 25 of the input area.

As described above, if the laser source according to one embodiment of the invention is to be optically stable, in other words, in order to set up at least one stable optical mode, the radius of curvature R of the concave mirror must be greater than the optical length L of the source defined by the relation L=n_{c}.L_{c}+nₑ.D+n₁.L₁ where n_{c}, nₑ are refraction indexes of the laser cavity material and the medium in the free space area inserted between the cavity and the guided optical element, respectively. n₁ is the effective index of the plane guide 25. L_{c}, D, L₁ are the lengths of the cavity 1, the free space area located between the cavity and the guided optical element, and the input area G₁, respectively.

The length L_{c} is given by the manufacturer of the laser cavity 1 and is usually between 100 and 1000 μm. For example, a laser diode with an emission wavelength λ=980 nm, a ribbon width 100 μm, length L_{c}=1000 μm and a refraction index n_{c}=3.3 can be used.

The length L₁ may vary. In some cases, the concave mirror may be arranged directly at the input to the optical element, which reduces the length of the input area to the bow h of the concave mirror. This length L₁ is such that L₁+L₂ enables good coupling in the microguide. L₁+L₂ will generally be more than 10000 μm.

If L=20000 μm, L₁ may be, for example, equal to 10000 μm for a glass substrate for which the effective index of the guide is equal to n₁=1.51 and a distance D for example equal to 10 μm when the area in free space is air with a refraction index equal to 1.

The dimensions of the concave mirror 7 are determined such that the diameter 2.w₀ of the optical beam 5 on the plane mirror R₁ (where w₀ is the radius of the said beam) is greater than the width of the ribbon of cavity 1. For example, for a 100 μm ribbon, we have w₀>50 μm. For example, w₀ may be equal to 60 μm.

The value w₀ is related to R and L by the relation w₀²=λ/π[L.(R−L)] ^{1/2} where λ is the wavelength considered of the light beam.

From this relation, and the inequality R>L, it can be deduced that R is greater than or equal to 50000 μm.

For example, R will be taken to be between 50000 and 60000 μm and L=20000 μm.

Furthermore, the diameter d of the mirror 7 is found by determining the dimension 2 w of the light beam on the said mirror starting from the relation:

$${w}^{2} = {\frac{λ R}{π} [ L / ( R - L ) ]}^{1 / 2}$$

where λ is the wavelength considered of the light beam.

The value of w found using the values of R and L given above is greater than about 80 μm (or even 100 μm).

The diameter d of the mirror must be greater than 2 w. Therefore, for example, d is taken to be greater than or equal to 200 μm.

Finally, the value of the bow h of the mirror will be chosen to be greater than 1 μm, so that it can be made in practice. The bow of the mirror is related to the diameter d and its radius of curvature R by the following relation: h/R=1−(1−d²/4R²)^{1/2}. For example, using the approximation h/R=d²/8R, d will be, for example, chosen equal to 600 to 800 μm for R greater than or equal to 50000 μm and h equal to about 1 μm.

FIG. 2 is a variant in the xz plane of the first embodiment showing focusing component 15 in free space located between the laser cavity 1 and the guided optical element 3.

For example, the focusing component(s) are made of collimators, and are used to optimise coupling between the laser cavity and the input to element 3, at least in the xz plane perpendicular to the guide plane.

The beam 5 output from the laser cavity is usually strongly divergent along the x axis and slightly divergent along the y axis. Therefore, it is particularly useful to focus the beam in the xz plane.

For example, these focusing components are made using a cylindrical, spherical type lens, a micro-lens or a fibre with an index gradient. An anti-reflection treatment of the focusing components may be made to prevent parasite optical cavities from being formed with the laser cavity.

FIG. 3 diagrammatically shows a sectional view of the source according to a second embodiment of the invention.

In this mode, the laser cavity is arranged directly on one of the walls parallel to the xy plane of the guided optical element at the area G₁ of the input guide. This type of assembly may be made by any conventional assembly technique.

In this embodiment, there is no free space between the cavity and the input guide area. The length L then corresponds to n_{c}.L_{c}+n₁.L₁ and for example may be equal to 20000 μm.

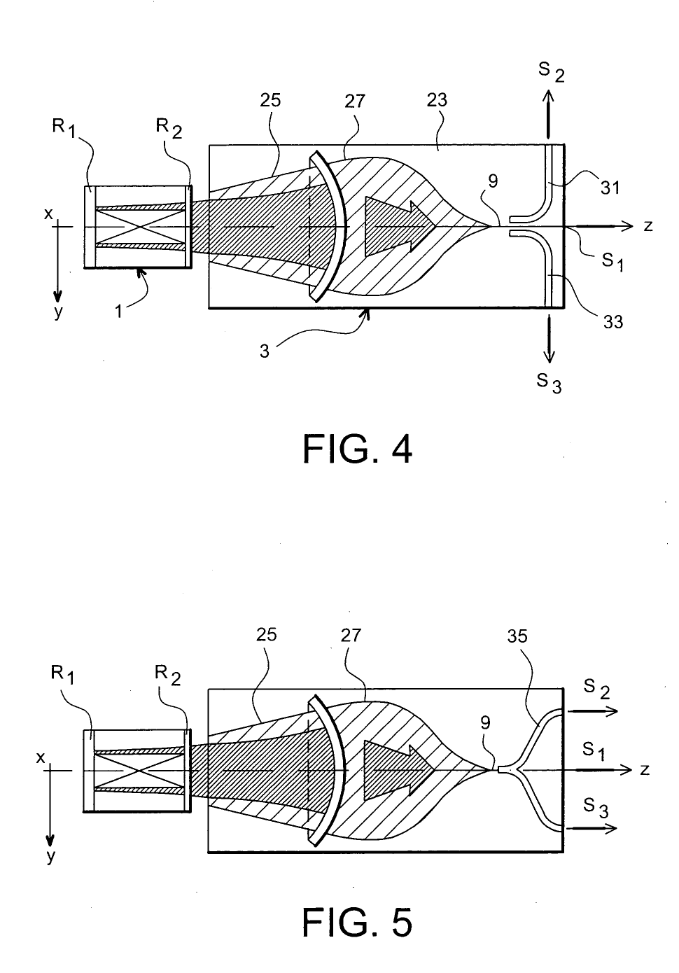

FIG. 4 diagrammatically shows a cross-section of a laser source with several optical outputs according to an embodiment of the invention.

In this embodiment, the area G₃ comprises two couplers 31, 33 located on each side of the microguide 9 such that the source comprises three outputs. The three outputs are output S₁ from the microguide 9, output S₂ from the coupler 31 and output S₃ from the coupler 33. The couplers 31, 33 are made by microguides in the substrate 23.

For example, in FIG. 4, output S₁ is located on a wall of the element 3 parallel to the xy plane while outputs S₂ and S₃ are located on walls that are separate from each other and are parallel to the xz plane. However, the outputs S₁, S₂ and S₃ may be arranged differently and in particular they may all be on one of the walls of the substrate.

FIG. 5 diagrammatically shows a variant of FIG. 4 in which the area G₃ comprises a 1 to 3 divider 35 connected to the microguide 9, and has three outputs S₁, S₂ and S₃. For example, in this figure, the three outputs S₁, S₂ and S₃ are located on the same wall parallel to the yx plane of the element. However, other configurations would also be possible.

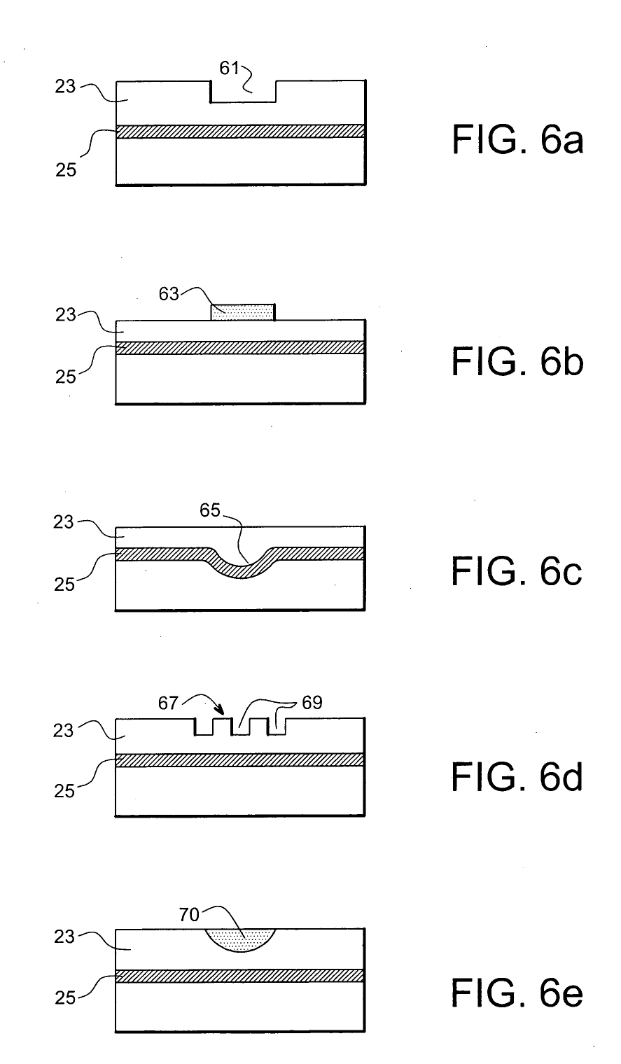

There are many ways of obtaining the concave mirror according to the invention by varying the effective index of the guide 25. FIGS. 6a to 6e illustrate five examples of concave mirrors that could be used in the invention, according to a cross-section along an xz plane.

In FIG. 6a, the effective index variation is obtained by an etching 61 located on substrate 23 above the planar guide 25 of the input area. This etching gives a concave cavity filled by the ambient medium, which is usually air. This cavity has a radius of curvature R and a diameter d, as defined above, in the yz plane not shown in this figure. For example, this cavity has a depth of a few 100 nm and a width in the xz plane of a few μm.

Therefore the mirror 7 is formed by this cavity 61 and the part of the guide 25 in which the cavity induces this index variation.

In FIG. 6b, this index variation is obtained by a local deposit of at least one layer 63 on the substrate above the planar guide 25. This deposit has a radius of curvature R and a diameter d in the yz plane (not shown) as defined above.

For a glass substrate, the deposit 63 may be, for example, made of silica, a metal or a polymer with a thickness varying between a few hundred nm and few tens of μm and a width in the xz plane of a few μm.

Therefore, the mirror 7 is formed by this layer 63 and the part of the guide 25 in which the layer induces this index variation.

In FIG. 6c, this index variation is obtained by local burial 65 of the planar guide 25 in the substrate. This burial 65 has a radius of curvature R and a diameter d in the yz plane (not shown) as defined above.

This burial is for example obtained in the case of a glass substrate with a guide made using the ion exchange technique by local diffusion through a mask, for example made of aluminium.

Therefore the mirror 7 is formed by the part of the guide 25 in which the local burial induces this index variation.

In FIG. 6d, this index variation is obtained by a Bragg grating 67 in the substrate above the plane guide 25. The grating 67 may comprise several periods to a few hundred periods. In this figure, the grating 67 comprises three periods comprising etchings 69 formed in the substrate. As described above, this grating has a radius of curvature R and a diameter d in the yz plane (not shown) as defined above. This grating is etched in the substrate, either by conventional photolithography and etching techniques, or by direct photo-registration when the substrate is photosensitive.

For example, if the period of the grating P=λ/2.n₁ for a guide with index n₁=1.5 and λ=980 nm, we obtain p=325 nm. The depth of the etchings may for example vary from a few tens to a few hundred nm and the width of these etchings in the xz plane may for example be p/2.

Therefore, the mirror 7 is formed by this grating 67 and the part of the guide 25 in which the grating induces this index variation.

Finally, FIG. 6e shows a mirror 7 obtained by an ion exchange located in the substrate. Thus, when the guide 25 has been made in the substrate, for example by a prior ion exchange step, the local ion exchange is achieved by the use of a bath for example containing Ag⁺ ions for a glass substrate containing Na⁺ ions and an appropriate mask such that the ion exchange is made in an area 70 of the substrate on a width of a few μm in the plane of the figure with parameters R and d as defined above.

Therefore the mirror 7 is formed by this area 70 and the part of the guide 25 in which the area induces this index variation.

As described above, the laser source according to an embodiment of the invention provides a way to generate single mode light beams or slightly multi-mode light beams on one or several outputs. The light beams can have a relatively high power. Consequently, the source according to an embodiment of the invention is applicable in many domains, and in particular as a pump for optical amplifiers or for fibre lasers or solid lasers or as a laser source for machining and/or for marking materials.

Furthermore, since numerous modifications and changes will readily occur to those of skill in the art, it is not desired to limit the invention to the exact construction and operation described herein. Accordingly, all suitable modifications and equivalents should be considered as falling within the spirit and scope of the present invention.

1. A laser source comprising:
a first optical element and a second optical element spaced apart from each other and defining a laser cavity therebetween, said laser cavity along with a lasing material therein being capable of emitting an optical beam; and
a guided optical element formed on a substrate, comprising:
a mirror, said mirror being concave in at least one guide plane of an input guide area of said guided optical element, said mirror forming an extended laser cavity with the laser cavity;
a microguide associated with an optical output of the laser source, said microguide defining an output area of said guided optical element,
wherein the input guide area of said guided optical element is capable of receiving the optical beam emitted by the laser cavity and capable of transmitting the optical beam to an adaptor guide area of said guided optical element located between the input guide area and the microguide, the adaptor guide area being capable of guiding the optical beam to the microguide.

2. A laser source according to claim 1, wherein at least one of the first and second optical elements is a plane mirror, and the laser cavity comprises a laser diode.

3. A laser source according to claim 1, wherein the laser cavity is arranged directly in contact with the guided optical element at the input guide area of the guided optical element.

4. A laser source according to claim 1, wherein one of said first optical element and said second optical element is disposed in contact with or adjacent to said input guide area of the guided optical element.

5. A laser source according to claim 1, wherein the laser cavity is spaced apart from the input guide area of the guided optical element by a free space area.

6. A laser source according to claim 5, further comprising:
a focusing component disposed between the cavity and the input guide area of the guided optical element,
wherein said focusing component is capable of focusing the optical beam emitted by the laser cavity into the input guide area, in a plane perpendicular to the guide plane of said input guide area.

7. A laser source according to claim 1, wherein the guided optical element is made from a glass substrate.

8. A laser source according to claim 1, wherein the input guide area comprises a planar guide, said planar guide is coupled to the adaptor guide area through the concave mirror.

9. A laser source according to claim 8, wherein the concave mirror is formed by a local variation of an effective index of the planar guide of the input guide area.

10. A laser source according to claim 9, wherein said local variation of the effective index is obtained by forming a cavity above the planar guide in the substrate,

11. A laser source according to claim 9, wherein said local variation of the effective index is obtained by local deposition of at least one layer of material above the planar guide on the substrate.

12. A laser source according to claim 9, wherein said local variation of the effective index is obtained by locally burying the planar guide.

13. A laser source according to claim 9, wherein said local variation of the effective index is obtained by an ion exchange located in the substrate above the planar guide.

14. A laser source according to claim 9, wherein said local variation of the effective index is obtained by forming a Bragg grating in the substrate above the planar guide.

15. A laser source according to claim 1, wherein the concave mirror is capable of filtering wavelengths of the optical beam.

16. A laser source according to claim 1, wherein the adaptor guide area comprises a tapered planar guide.

17. A laser source according to claim 16, wherein the tapered planar guide in the adaptor guide area is adiabatic.

18. A laser source according to claim 1, further comprising:
a divider having an input and a plurality of outputs, said devider being disposed in the output area of the guided optical element,
wherein the input of said divider is connected to the microguide such that the plurality of outputs of the divider constitute a plurality of outputs of the laser source.

19. A laser source according to claim 1, further comprising:
a plurality of couplers disposed in the output area of the guided optical element,
wherein each coupler in said plurality of couplers is coupled with the microguide such that the microguide and each of the plurality of couplers form a plurality of outputs of the laser source.

20. A laser source according to claim 1, wherein the concave mirror has a radius of curvature R greater than or equal to an optical length L of the laser source, the optical length of the laser source is defined by the relation:
L=n_{c}.L_{c}+nₑ.D+n₁.L₁
where n₁ is an effective index of the input guide area, n_{c} is a refraction index of the lasing material in the laser cavity, nₑ is a refraction index of a medium in a free space area between the laser cavity and the guided optical element, L_{c} is a length of the laser cavity, D is a length of the free space area between the laser cavity and the guided optical element, and L₁ is a length of the input guide area of the guide optical element.

21. A laser source according to claim 20, wherein said laser cavity is a ribbon laser cavity.

22. A laser source according to claim 21, wherein the geometrical characteristics of the concave mirror are defined using the following equalities and inequalities:
W₀² (λ/π)[L.(R−L)]^{1/2} and 2W₀>lᵣ
W²=(λR/π) [L/(R−L)]^{1/2}
R>L
L=n_{c}.L_{c}+nₑ.D+n₁.L₁
H/R=1−(1−d²/4R²)^{1/2}
d>2W
where λ is a wavelength of the light beam, w₀ is a radius of the light beam on a plane mirror of the laser cavity, lᵣ is a width of the ribbon of the laser cavity, R is a radius of curvature of the concave mirror, L is an optical length of the laser source, w is a radius of the light beam on the concave mirror, h is a bow of the concave mirror in the guide plane and d is a diameter of the concave mirror.
